(19) United States
(12) Patent Application Publication
(10) Pub. No.: US 2008/0038849 A1
(43) Pub. Date: Feb. 14, 2008

(54) Evaluation method of fine pattern, manufacturing method of device having the fine pattern

(75) Inventors: Takamitsu Orimoto, Kawasaki (JP); Ryuei Ono, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/647,166

(22) Filed: Dec. 29, 2006

(30) Foreign Application Priority Data
Aug. 11, 2006 (JP) 2006-220474

(51) Int. Cl. H01L 21/66

(52) U.S. Cl. 438/17; 438/18; 438/926

(57) ABSTRACT

An evaluation method includes the steps of forming a dummy pattern having a patterned part with the same critical dimension as a minimum critical dimension of an actual device having a fine pattern that is so fine that a probe for a continuity test cannot be connected to both ends of the fine pattern, in forming the fine pattern, while connecting both ends of the dummy pattern to a pair of pads to which the probe is connectible, performing the continuity test of the dummy pattern using the probe and the pads, and evaluating an insulating characteristic of the fine pattern based on a result of the continuity test.

This application claims the right of a foreign priority based on Japanese Patent Application No. 2006-220474, filed on Aug. 11, 2006, which is hereby incorporated by reference herein in its entirety as if fully set forth herein.

### BACKGROUND OF THE INVENTION

The present invention relates generally to a pattern evaluating method, and more particularly to an evaluation method of a fine pattern in a device when a probe for a continuity test cannot be connected to the fine pattern. The present invention is suitable, for example, for an evaluation method of a coil pattern in a write head device that is installed in a hard disc drive (“HDD”).

Along with the recent spread of the Internet etc., a demand for inexpensively providing an HDD that records information is growing. In order to meet this demand, efficient manufacture of the HDD and the improved yield are required.

The HDD includes a magnetic head that is comprised of a read head device and a write head device. Among them, the write head device forms a magnetic circuit that includes bottom and top magnetic poles, and one or more coil layers. When the current flows in the coil, the upper and lower magnetic poles are magnetized, and information is recorded in the disc due to the magnetic flux leaked from the magnetic gap. See, for example, Japanese Patent application, Publication No. 2005-004935, FIG. 6 and paragraphs 0019 and 0020.

In general, the write head device is formed by stacking a bottom magnetic pole, an insulating layer, another insulating layer, and a top magnetic pole on a substrate in this order. In the conventional characteristic test of the layered substrate, pads are connected to the layered substrate via lead wires after layering is completed, and probes are put on the pads. The conventional method thus cannot determine whether coil patterning has succeeded or not just after the coil pattern is formed, because the coil pattern is finer than the probe. In addition, one end of the coil pattern is drawn out of the coil but the other end remains inside the coil, and the probe cannot be connected to the other end. One measure that draws the other end out of the coil needs an insulating layer that insulates the other end from the coil, and reduces the throughput.

Other prior art include Japanese Patent Application, Publication No. 2006-013116.

However, the conventional evaluation method that uses the layered substrate cannot determine whether the coil is defective or non-defective until the layered substrate is finished, and needs a long time period for the evaluation, lowering the throughput. In addition, the conventional evaluation method has a difficulty in identifying the defective part lowering both the throughput and the yield, because each layer in the layered structure cannot be observed by a scanning electron microscope (“SEM”) once the layered structure is completed.

### BRIEF SUMMARY OF THE INVENTION

It is an exemplified object of the present invention to provide an evaluation method that improves both the throughput and the yield, and the device manufacturing method using the evaluation method.

An evaluation method according to one aspect of the present invention includes the steps of forming a dummy pattern having a patterned part with the same critical dimension as a minimum critical dimension of an actual device having a fine pattern that is so fine that a probe for a continuity test cannot be connected to both ends of the fine pattern, in forming the fine pattern, while connecting both ends of the dummy pattern to a pair of pads to which the probe is connectible, performing the continuity test of the dummy pattern using the probe and the pads, and evaluating an insulating characteristic of the fine pattern based on a result of the continuity test. This evaluation method forms the dummy pattern in forming the fine pattern., evaluates the dummy pattern, and evaluates the fine pattern based on the evaluation result of the dummy pattern. When the dummy pattern is defective, the fine pattern is observed with an SEM, and the detective part can be easily and promptly identified. Thus, the yield and the throughput improve. Since the dummy pattern has the patterned part with the minimum CD of the actual device, the evaluation of the insulating characteristic of the dummy pattern, such as disconnection and short circuit, can be regarded as the evaluation of the fine pattern.

Preferably, the forming step forms a first dummy pattern that electrically connects the pair of pads to each other, and a second dummy pattern that disconnects the pair of pads from each other, wherein the performing step tests a continuity of each of the first and second dummy patterns. The reliability improves through two types of continuity tests. The fine pattern of the actual device is, for example, a coil pattern of a write head device

A method according to another aspect of the present invention of manufacturing a device having a layered structure that has a fine pattern that is so fine that a probe for a continuity test cannot be connected to both ends of the fine pattern includes the steps of forming one layer of the fine pattern in the layered structure evaluating an insulating characteristic of the fine pattern using the above evaluation method, and stacking another layer on the one layer after the evaluating step evaluates that the one layer is non-defective. This device manufacturing method efficiently evaluates the fine pattern just after one layer having the fine pattern is formed before the layered structure is completed, and stacks the remaining layers only if the one layer is evaluated non-defective.

Other objects and further features of the present invention will become readily apparent from the following description of the preferred embodiments with reference to accompanying drawings.

### BRIEF DESCRIPTION OF THE DRAWINGS

FIG. 1 is a schematic plane view of a substrate according to one embodiment of the present invention.

FIGS. 2A and 2B are partially enlarged sectional views of the substrate shown in FIG. 1.

FIG. 3 is a flowchart for explaining a device manufacturing method according to one embodiment of the present invention.

FIG. 4 is a flowchart for explaining one step in detail in the device manufacturing method shown in FIG. 3.

FIG. 5 is a schematic sectional view of a lower coil layer.

FIG. 6 is a schematic sectional view of an upper coil layer.

### DETAILED DESCRIPTION OF THE PREFERRED EMBODIMENTS

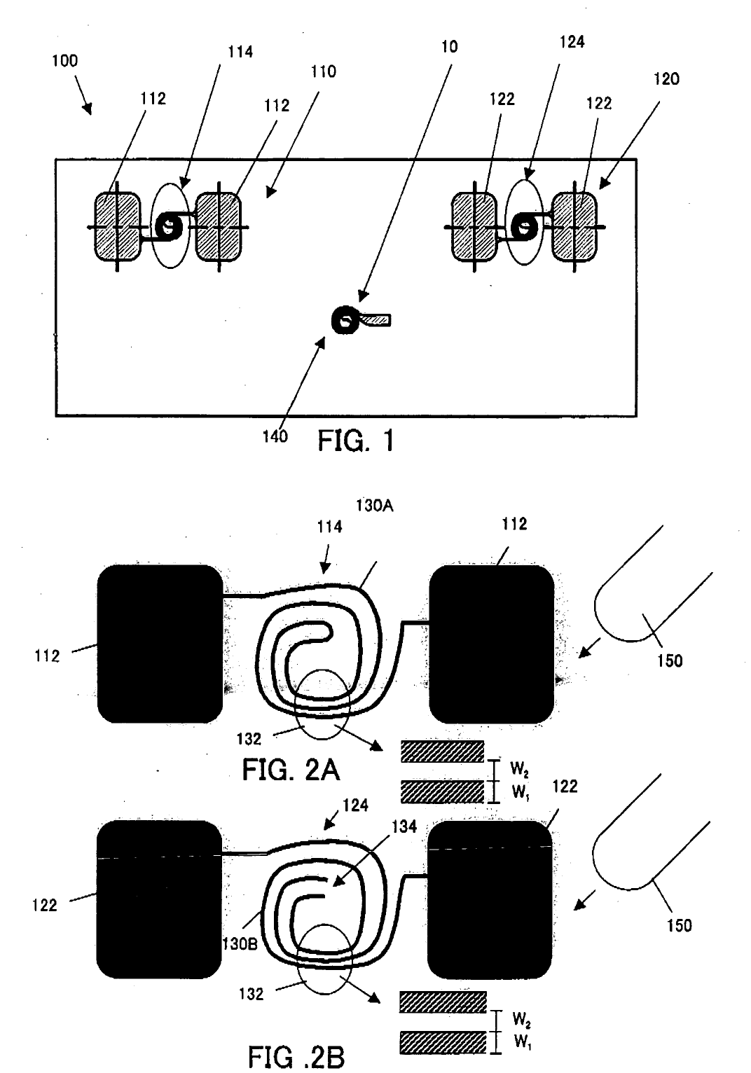

Referring now to the accompanying drawings, a description will be given of an evaluation method of a fine pattern according to one embodiment of the present invention. This embodiment discusses a coil pattern of a write head device in a magnetic head as an example of a fine pattern 10. The fine pattern 10 is a pattern of an upper coil pattern or lower coil pattern shown in FIG. 6 in Japanese Patent application, Publication No. 2005-004935. As described above, a pair of probes 150 for a continuity test cannot be connected to both ends of the fine pattern 10. Here, FIG. 1 is a schematic plane view of a substrate 100. FIG. 2A is a schematic enlarged plane view of a first evaluation section 110. FIG. 2B is a schematic enlarged plane view of a second evaluation section 120.

The substrate 100 includes the first evaluation section 110, the second evaluation section 120, and a product section 140.

The first evaluation section 110 is a place used to evaluate the continuity of the dummy pattern 130A, and includes a pair of pads 112 and a monitor part 114, as shown in FIG. 2A. A pair of pads 112 are electrically connected to both ends of the dummy pattern 130A. A dummy pattern 130A is placed on the monitor part 114. Both pads 112 are connectible to the probes 150 for the continuity test of the continuity of the dummy pattern 130A.

The second evaluation section 120 is a place used to evaluate a disconnection of the dummy pattern 130B, and includes a pair of pads 122 and a monitor part 124, as shown in FIG. 2B. A pair of pads 122 are electrically connected to both ends of the dummy pattern 130B. The dummy pattern 130B is placed on the monitor part 124. Both pads 122 are connectible to the probes 150 so as to detect the disconnection of the dummy pattern 130B.

Both the first and second evaluation sections 110 and 120 detect two types of insulating characteristics of the dummy pattern, and improve the reliability.

Both the dummy patterns 130A and 130B have a patterned part 132 with the same critical dimension (“CD”), such as W₁ and W₂, as the minimum CD of the line and space (not shown) of the fine pattern 10. As a result, evaluations of the dummy patterns 130A and 130B through their continuity tests can be regarded as the evaluation of the insulating characteristic (patterning characteristic) of the fine pattern 10. The patterned part 132 is enlarged in FIGS. 2A and 2B, and the width W₁ and interval W₂ of the pattern are the same as those (not shown) of the fine pattern 10. The patterned part 132 is a part that has the minimum CD in each of the dummy patterns 130A and 130B.

Neither the dummy pattern 130A nor 130B has completely the same shape as that of the fine pattern 10. The fine pattern 10 needs to generate a magnetic flux when wound around the magnetic core material, and the structures shown in FIGS. 2A and 2B cannot generate the magnetic flux. The evaluation method of this embodiment evaluates not the shape of the fine pattern 10 but its insulating or patterning characteristic, such as disconnection and short circuit, and the dummy pattern does not have to possess the same shape as that of the fine pattern 10.

The dummy patterns 130A and 130B are different from each other in that the dummy pattern 130A has no disconnection part but the dummy pattern 130B has a disconnection part 134.

The fine pattern 10 is placed on the product section 140. Thus, a pair of evaluation sections 110, 120 and the product section 140 are provided on the same substrate 100.

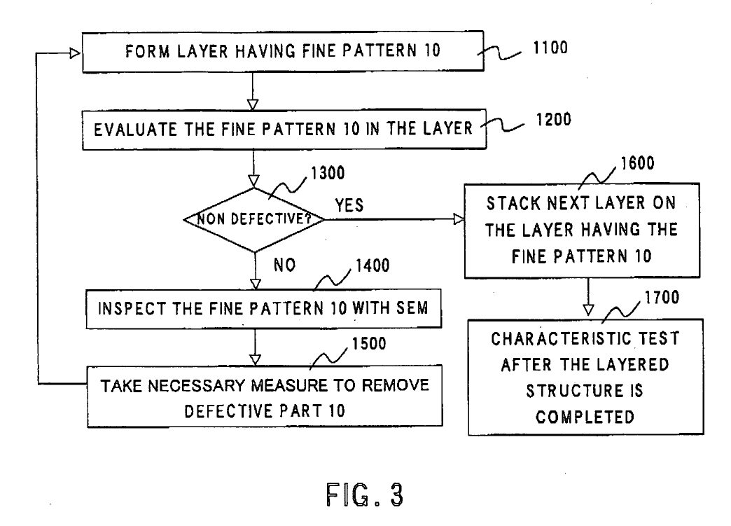

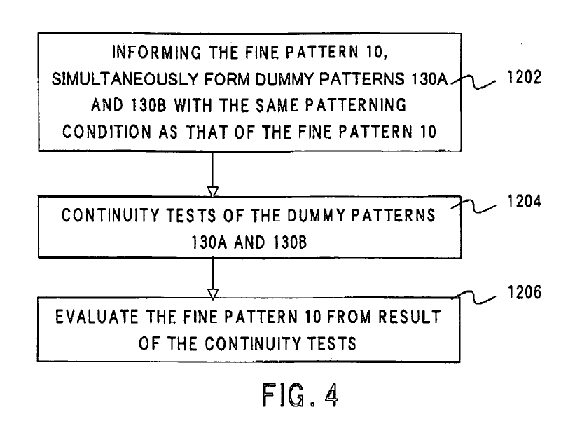

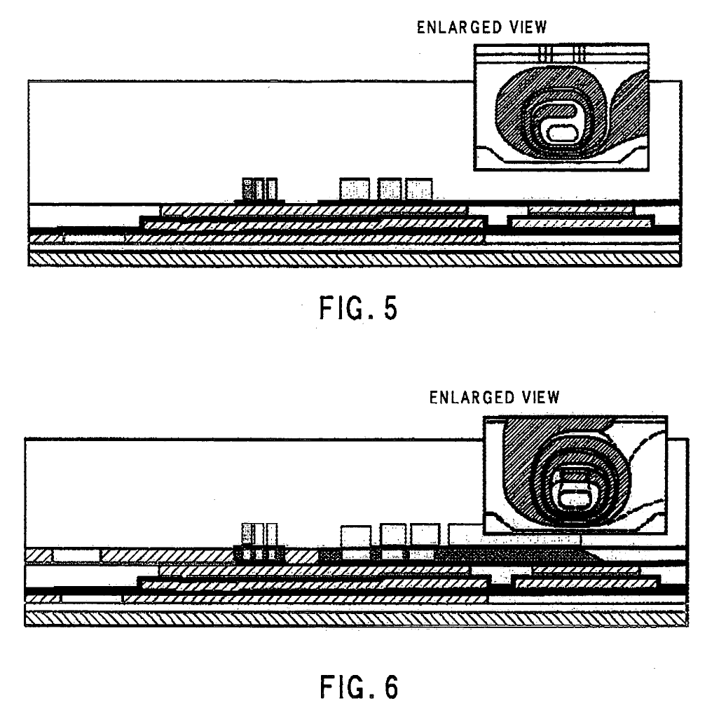

Referring now to FIGS. 3 and 4, a description will be given of the device manufacturing method according to one embodiment of the present invention. Here, FIG. 3 is a flowchart of the device manufacturing method. First, a layer having a fine pattern 10 is formed (step 1100). For example, after the bottom magnetic pole is formed, the lower coil is formed. FIG. 5 is a partially enlarged, longitudinal section and cross-section of the layered structure after the lower coil is formed. Next, the fine pattern in that layer is evaluated (step 1200). The evaluation method of this embodiment is executed just after the lower coil pattern is formed.

Referring now to FIG. 4, a detailed description of the evaluation method (step 1200) will be given. Here, FIG. 4 is a flowchart of the evaluation method of this embodiment.

First, in forming the fine pattern 10, the dummy patterns 130A and 130B are simultaneously formed with the same patterning condition as that of the fine pattern 10 (step 1202). The identical patterning condition between the dummy patterns 130A and 130B and the fine pattern 10 improves the reliability in regarding the evaluation of the dummy pattern as the evaluation of the fine pattern.

Next, the continuity test is performed for each of the dummy patterns 130A and 130B (step 1204). Next, the fine pattern 10 is evaluated from the result of the continuity test (step 1206). FIG. 2A electrically connects the pads 112 to each other. When the probes 150 are put on both pads 112, the electrical connection should be confirmed. Therefore, when the test result of the step 1204 indicates no continuity, the step 1206 evaluates the fine pattern 10 defective. FIG. 2B disconnects the pads 122 from each other. When the probes 150 are put on both pads 122, the disconnection should be confirmed. Therefore, when the test result of the step 1204 indicates continuity, the step 1206 evaluates the fine pattern 10 defective. The coil is made of Cu plating. For example, a Ti/Cu plating base is formed on the substrate, and various processes follow, such as resist application, exposure, development, etching, plating, resist removal, and ion-milling plating base removal. For example, insufficient plating due to foreign particles would disconnect part that should be electrically connected. When the resist exfoliates and plating penetrates below the resist, part that should be disconnected becomes conductive.

Turning back to FIG. 3, whether the step 1206 evaluates non-defective is determined (step 1300). When the step 1300 determines the fine pattern 10 defective, the fine pattern 10 is observed with the SEM (step 1400). Thereby, the defective part is easily and promptly identified. Next follows a measure, such as a resist application and review of an exposure condition, necessary to remove the defective part (step 1500), and the procedure returns to the step 1100 to repeat the formation of the lower coil layer. When the step 1300 determines the fine pattern 10 non-defective, the next layer is stacked on the layer having the fine pattern 10 (step 1600). For example, an insulating layer is formed on the lower coil layer, and an upper coil layer is formed. The same evaluation is conducted for the upper coil layer. FIG. 6 is a partially enlarged, longitudinal section and cross-section of the layered structure after the upper coil is formed. When the layered structure is completed, the characteristic test of the (write head) device follows (step 1700) as in the conventional method. The head device that has passed the characteristic test is mounted as the magnetic head. When the head device fails the characteristic test, a necessary measure is performed to remove the defective part.

Efficiently, this embodiment evaluates the fine pattern just after one layer having the fine pattern is formed before the layered structure is completed, and stacks the remaining layers only if the one layer is evaluated non-defective. In addition, this embodiment facilitates a continuity test using the probe and the dummy pattern connected to the pads instead of the fine pattern. The evaluation of the fine pattern before the layered structure including the fine pattern is completed improves the throughput. When the dummy pattern is defective, the fine pattern in the one layer can be observed with the SEM, and the defective part can be identified easily and promptly. Thus, both the yield and the throughput improve. Since the dummy pattern has a patterned part having the minimum CD of the actual device, the evaluation of the insulating characteristic, such as disconnection and short circuit, of the dummy pattern can be regarded as the evaluation of the fine pattern.

Further, the present invention is not limited to these preferred embodiments, and various modifications and variations may be made without departing from the spirit and scope of the present invention. For example, the present invention is applicable both an evaluation and manufacture of a device having a fine pattern to which a probe for a continuity test cannot be connected, as well as a magnetic head.

What is claimed is:

1. An evaluation method comprising the steps of:
forming a dummy pattern having a patterned part with the same critical dimension as a minimum critical dimension of an actual device having a fine pattern that is so fine that a probe for a continuity test cannot be connected to both ends of the fine pattern, in forming the fine pattern, while connecting both ends of the dummy pattern to a pair of pads to which the probe is connectible;
performing the continuity test of the dummy pattern using the probe and the pads; and
evaluating an insulating characteristic of the fine pattern based on a result of the continuity test.

2. An evaluation method according to claim 1, wherein said forming step forms a first dummy pattern that electrically connects the pair of pads to each other, and a second dummy pattern that disconnects the pair of pads from each other, and
wherein said performing step tests a continuity of each of the first and second dummy patterns.

3. An evaluation method according to claim 1, wherein the fine pattern of the actual device is a coil pattern of a write head device.

4. A method of manufacturing a device having a layered structure that has a fine pattern that is so fine that a probe for a continuity test cannot be connected to both ends of the fine pattern, said method comprising the steps of:
forming one layer of the fine pattern in the layered structure;
evaluating an insulating characteristic of the fine pattern using an evaluation method according to claim 1; and
stacking another layer on the one layer after said evaluating step evaluates that the one layer is non-defective.
